(19) United States
(12) Patent Application Publication
(10) Pub. No.: US 2024/0048111 A1
(43) Pub. Date: Feb. 8, 2024

(54) MANUFACTURING METHOD OF PIEZOELECTRIC VIBRATION ELEMENT

(71) Applicant: TXC Corporation, Taipei City (TW)

(72) Inventors: Po-Sheng Huang, Taipei City (TW); Chieh-Jen Cho, Taipei City (TW); Shih-Feng Hsueh, Taipei City (TW); Ching-Jui Chuang, Taipei City (TW); Tzu-Fan Chen, Taipei City (TW); Chiu-Hua Chen, Taipei City (TW)

(73) Assignee: TXC Corporation, Taipei City (TW)

(21) Appl. No.: 17/940,007

(22) Filed: Sep. 8, 2022

(30) Foreign Application Priority Data
Aug. 2, 2022 (TW) 111129015

(51) Int. Cl. H03H 3/02; H03H 9/19

(52) U.S. Cl. CPC H03H 3/02; H03H 9/19

(57) ABSTRACT

A manufacturing method of a piezoelectric vibration element includes at least the following steps. Quartz wafer is provided. A first metal material layer and a second metal material layer are fully formed on a first surface and a second surface of the quartz wafer, respectively. A first photoresist material layer and a second photoresist material layer are fully formed on the first metal material layer and the second metal material layer, respectively. Only the first photoresist material layer is performed to an exposure and development process to form a first patterned photoresist layer. A portion of the first metal material layer is removed by the first patterned photoresist layer to form a metal pattern. The first patterned photoresist layer and the second photoresist material layer are removed.

### CROSS-REFERENCE TO RELATED APPLICATION

This application claims the priority benefit of Taiwan application serial no. 111129015, filed on Aug. 2, 2022. The entirety of the above-mentioned patent application is hereby incorporated by reference herein and made a part of this specification.

### BACKGROUND

### Technical Field

The disclosure generally relates to a manufacturing method, and more particularly, to a manufacturing method of piezoelectric vibration element.

### Description of Related Art

With the present trend of miniaturizing, exposure development processes are often used in the manufacturing method of piezoelectric vibration elements (such as quartz oscillators) to replace the cutting and grinding process to meet the precise requirements of quartz oscillators. However, the more exposure and development processes are used, the higher the manufacturing cost will be in terms of manpower, masks, and machines. Therefore, it is a challenge to reduce the manufacturing cost while maintaining the precise requirements of the quartz oscillator.

### SUMMARY

The disclosure provides a manufacturing method of a piezoelectric vibration element, which reduces the manufacturing cost while maintaining the precise requirements of the piezoelectric vibration element.

The manufacturing method of the piezoelectric vibration element of the disclosure includes at least the following steps. Quartz wafer is provided. A first metal material layer and a second metal material layer are fully formed on a first surface and a second surface of the quartz wafer, respectively. A first photoresist material layer and a second photoresist material layer are fully formed on the first metal material layer and the second metal material layer, respectively. Only the first photoresist material layer is performed to an exposure and development process to form a first patterned photoresist layer. A portion of the first metal material layer is removed by the first patterned photoresist layer to form a metal pattern. The photoresists of the first surface and the second surface are completely removed.

In an embodiment of the disclosure, the above manufacturing method further includes the following steps. A third photoresist material layer and a fourth photoresist material layer are fully formed on the first metal material layer and the second metal material layer, respectively. Exposure and development processes are respectively performed on the third photoresist material layer and the fourth photoresist material layer to form a second patterned photoresist layer and a third patterned photoresist layer.

In an embodiment of the disclosure, the above manufacturing method further includes the following steps. A first portion of the quartz wafer is removed by the metal pattern and the second patterned photoresist layer to form a groove pattern extending from the first surface into the quartz wafer.

In an embodiment of the disclosure, after the groove pattern is formed, the above manufacturing method further includes the following steps. A portion of the metal pattern is removed by the second patterned photoresist layer. A portion of the second metal material layer is removed by the third patterned photoresist layer. A second portion of the quartz wafer is removed, such that the plurality of groove patterns are extended and penetrated through to the second surface.

In an embodiment of the disclosure, an element region, a support region, and a dividing region are formed after the second portion of the quartz wafer is removed as described above. The dividing region is located between the element region and the support region.

In an embodiment of the disclosure, the second patterned photoresist layer, the third patterned photoresist layer, another portion of the metal pattern, and another portion of the second metal material layer are removed after the element region, the support region, and the dividing region are formed.

In an embodiment of the disclosure, the support structure on the support region and the piezoelectric vibration element on the element region form an H-structure after the second portion of the quartz wafer is removed.

In an embodiment of the disclosure, the piezoelectric vibration element is a flat sheet.

In an embodiment of the disclosure, the piezoelectric vibration element is not in the shape of a tuning fork.

In an embodiment of the disclosure, a thickness of the piezoelectric vibration element is at least less than 50 micrometers.

Based on the above, the manufacturing method of the piezoelectric vibration element of the disclosure is designed to simplify the process. That is, the manufacturing method of the piezoelectric vibration element of the disclosure only performs one exposure and development process on the photoresist material layer on one side of the quartz wafer, and does not perform a secondary exposure and development process on the photoresist material layer on two sides of the quartz wafer at the same time. The metal pattern defined by the photoresist layer after the exposure and development process may still be used to define the plane size of the piezoelectric vibration element on one side, which reduces the manufacturing cost while maintaining the precise requirements of the piezoelectric vibration element.

In order to make the above-mentioned features and advantages of the disclosure comprehensible, embodiments accompanied with drawings are described in detail below.

### BRIEF DESCRIPTION OF THE DRAWINGS

FIG. 1A to FIG. 1J are partial cross-sectional schematic views of the manufacturing method of the piezoelectric vibration element according to an embodiment of the disclosure.

FIG. 2 is a schematic top view of the quartz wafer after being made into a piezoelectric vibration element according to another embodiment of the disclosure.

### DESCRIPTION OF THE EMBODIMENTS

Directional terms (for example, upper, lower, right, left, front, back, top, and bottom) used herein only refer to the graphical use, and are not intended to imply absolute orientation.

Unless otherwise clearly indicated, any method provided in this disclosure should not be construed as requiring steps therein to be performed in a particular order.

The disclosure is more fully described with reference to the figures of the present embodiments. However, the disclosure can also be implemented in various different forms, and is not limited to the embodiments in the present specification. Thicknesses, dimensions, and sizes of layers or regions in the drawings are exaggerated for clarity. The same reference numbers are used in the drawings and the description to indicate the same or like parts, which are not repeated in the following embodiments.

Unless otherwise defined, all terms (including technical and scientific terms) used herein have the same meaning as that commonly understood by one of ordinary skill in the art to which this disclosure belongs.

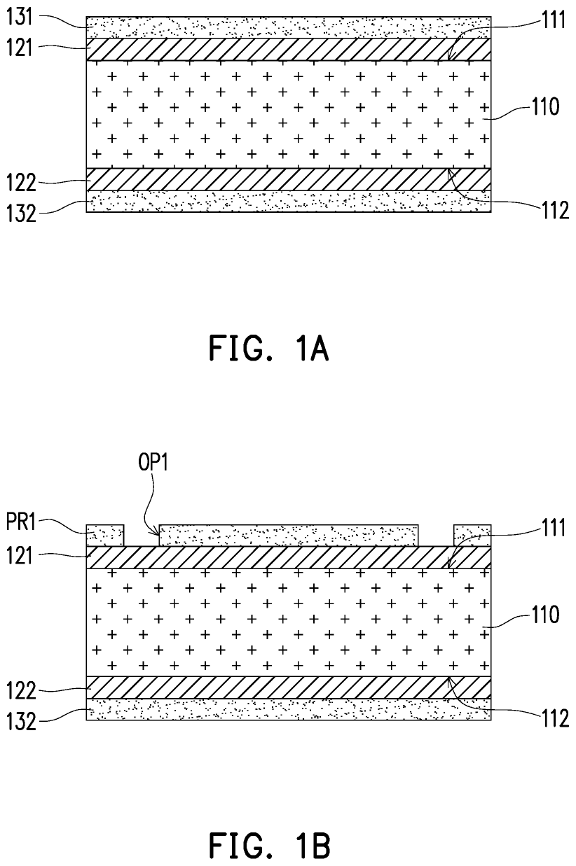

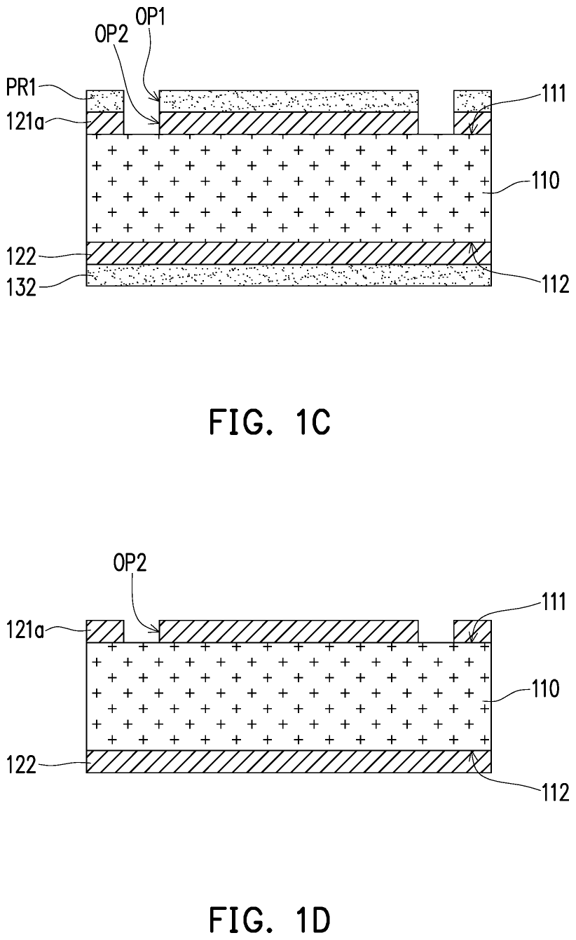

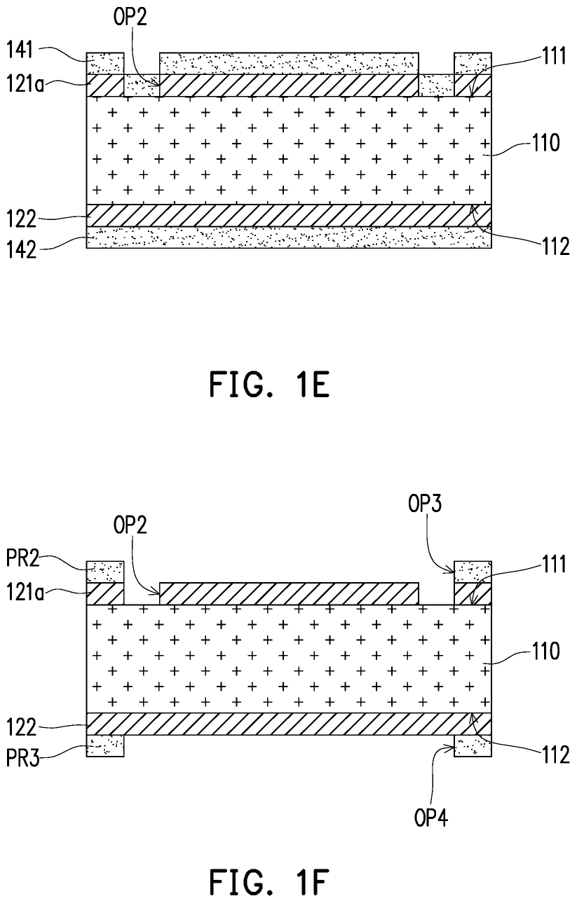

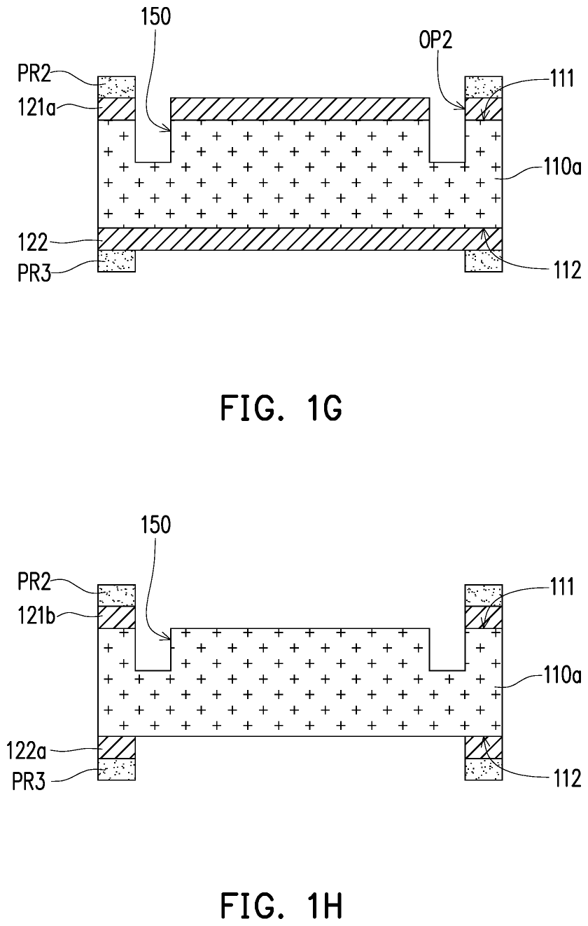

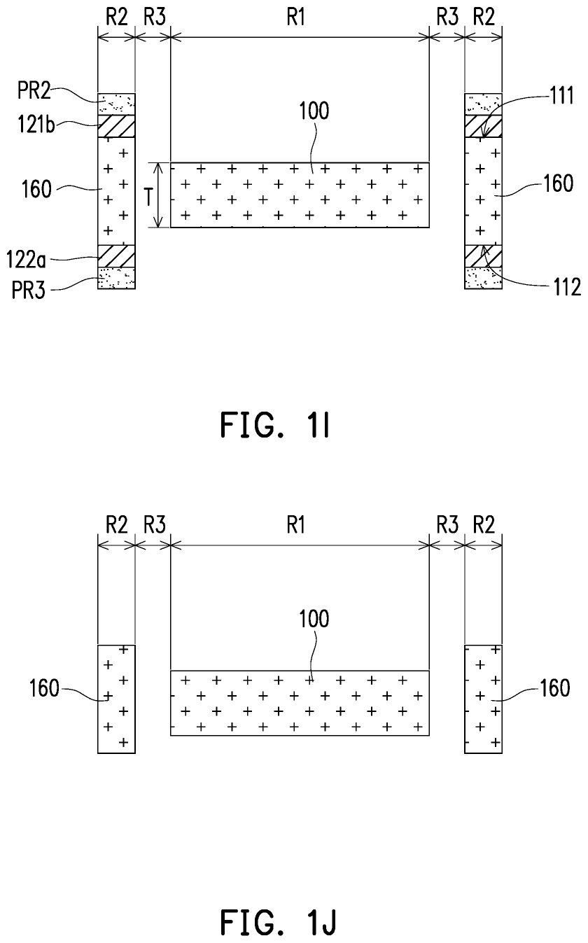

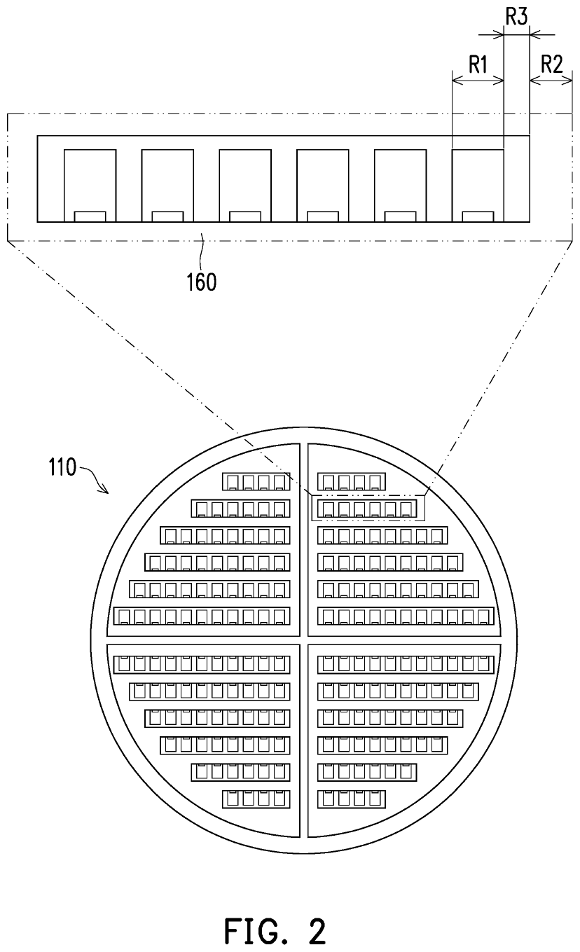

FIG. 1A to FIG. 1J are partial cross-sectional schematic views of the manufacturing method of the piezoelectric vibration element according to an embodiment of the disclosure. In this embodiment, the manufacturing method of the piezoelectric vibration element may include the following steps. FIG. 2 is a schematic top view of the quartz wafer after being made into a piezoelectric vibration element according to another embodiment of the disclosure.

Referring to FIG. 1A, first, a quartz wafer 110 is provided. The quartz wafer 110 has a first surface 111 and a second surface 112 opposite to each other. The quartz wafer 110 may be a 3-inch wafer or a 4-inch wafer, and the thickness is, for example, between 80 micrometers and 100 micrometers, but the disclosure is not limited to this. The size and thickness of the quartz wafer 110 may be determined according to actual design requirements.

With continued reference to FIG. 1A, a first metal material layer 121 and a second metal material layer 122 are fully formed on the first surface 111 and the second surface 112, respectively. “Fully formed” may refer to completely covering the surface of the quartz wafer 110. Next, a first photoresist material layer 131 and a second photoresist material layer 132 are fully formed on the first metal material layer 121 and the second metal material layer 122, respectively. The material of the first metal material layer 121 and the second metal material layer 122 is, for example, gold or other suitable metal materials. The first metal material layer 121 and the second metal material layer 122 may be formed by a metal deposition process or other suitable processes. In addition, the material of the first photoresist material layer 131 and the second photoresist material layer 132 is, for example, a positive photoresist or a negative photoresist. The first photoresist material layer 131 and the second photoresist material layer 132 may be formed by a coating process or other suitable processes.

Referring to FIG. 1B, only the first photoresist material layer 131 is performed to an exposure and development process to form a first patterned photoresist layer PR1. In other words, the exposure and development process is not performed on the second photoresist material layer 132. Therefore, the exposure and development process may be performed only once in this manufacturing stage, and the second photoresist material layer 132 may completely cover the second metal material layer 122. Furthermore, the first patterned photoresist layer PR1 may have a plurality of openings OP1 to expose a portion of the first metal material layer 121.

Referring to FIG. 1C, a portion of the first metal material layer 121 is removed by the first patterned photoresist layer PR1 to form a metal pattern 121a. For example, the first photoresist material layer PR1 may be used as an etching mask, and an etching process is performed on the first metal material layer 121 to remove the first metal material layer 121 exposed by the opening OP1 of the first patterned photoresist layer PR1 and form metal pattern 121a. Corresponding to the opening OP1, the metal pattern 121a may also form an opening OP2 to expose the first surface 111 of a portion quartz wafer 110.

Referring to FIG. 1D, the first patterned photoresist layer PR1 and the second photoresist material layer 132 are removed. Accordingly, the manufacturing method of the piezoelectric vibration element of this embodiment is designed to simplify the process. That is, the manufacturing method of the piezoelectric vibration element of this embodiment only performs one exposure and development process on the photoresist material layer on one side (such as the first surface 111) of the quartz wafer 110, and does not perform a secondary exposure and development process on the photoresist material layer on two sides (such as the first surface 111 and the second surface 112) of the quartz wafer at the same time. The metal pattern 121a defined by the photoresist layer after the exposure and development process may still be used to define the plane size of the subsequent piezoelectric vibration element 100 (as shown in FIG. 1J) on one side, which reduces the manufacturing cost while maintaining the precise requirements of the piezoelectric vibration element 100.

The manufacturing method of the piezoelectric vibration element of this embodiment is further described in the following. Referring to FIG. 1E, a third photoresist material layer 141 and a fourth photoresist material layer 142 are fully formed on the metal pattern 121a and the second metal material layer 122, respectively. For example, a portion of the third photoresist material layer 141 may be formed on the metal pattern 121a, and another portion of the third photoresist material layer 141 may be formed within the opening OP2 of the metal pattern 121a, but the disclosure is not limited thereto. The material of the third photoresist material layer 141 and the fourth photoresist material layer 142 is, for example, a positive photoresist or a negative photoresist, and the third photoresist material layer 141 and the fourth photoresist material layer 142 may be formed by a coating process or other suitable processes.

Referring to FIG. 1F, exposure and development processes are respectively performed (secondary exposure and development process is performed) on the third photoresist material layer 141 and the fourth photoresist material layer 142 to form a second patterned photoresist layer PR2 and a third patterned photoresist layer PR3. For example, the second patterned photoresist layer PR2 has an opening OP3 to expose a portion of the metal pattern 121a and the opening OP2 of the metal pattern 121a, while the third patterned photoresist layer PR3 has an opening OP4 to expose the second metal material layer 122. In here, only a portion of the first surface 111 is exposed, and the second surface 112 may be completely covered.

Referring to FIG. 1G, the first portion (forming a quartz wafer 110a) of the quartz wafer 110 is removed by the metal pattern 121a and the second patterned photoresist layer PR2 to form a groove pattern 150 extending from the first surface 111 into the quartz wafer 110. The quartz wafer 110a may not be completely penetrated after the groove pattern 150 is formed.

In some embodiments, the metal pattern 121a and the second patterned photoresist layer PR2 may be used as etching masks, and an etching process is performed on the quartz wafer 110 to remove the quartz wafer 110 exposed by the opening OP2 of the metal pattern 121a. The opening OP2 may connect the groove pattern 150. On the other hand, since the second surface 112 of the quartz wafer 110 is completely covered by the second metal material layer 122, etching behavior on the second surface 112 in this manufacturing stage is avoided. In this way, the plane size (for example, 1 millimeter (mm)*1 millimeter) of the piezoelectric vibration element 100 may be first defined on a single surface, but the disclosure is not limited thereto.

Referring to FIG. 1H, a portion of the metal pattern 121a is removed by the second patterned photoresist layer PR2, and a portion of the second metal material layer 122 is removed by the third patterned photoresist layer PR3. For example, the second patterned photoresist layer PR2 and the third patterned photoresist layer PR3 may be used as etching masks, and etching processes are respectively performed on the metal pattern 121a and the second metal material layer 122 to expose another portion of the surface of the quartz wafer 110. Therefore, the metal pattern 121a and the second metal material layer 122 may be the only remaining portions located on two sides of the quartz wafer 110a, that is, a metal pattern 121b and a second metal material layer 122a. The first surface 111 may be in a projected platform shape within the groove pattern 150, but the disclosure is not limited thereto.

Referring to FIG. 1I, a second portion of the quartz wafer 110a is removed, such that the plurality of groove patterns 150 are extend and penetrated through to the second surface 112. Therefore, an element region R1, a support region R2, and a dividing region R3 is formed, and the dividing region R3 is located between the element region R1 and the support region R2. The piezoelectric vibration element 100 is formed in the element region R1, and a support structure 160 is formed in the support region R2. In addition, a thickness T of the piezoelectric vibration element 100 is defined in this manufacturing stage. For example, the thickness T of the piezoelectric vibration element 100 is at least less than 50 micrometers, but the disclosure is not limited thereto.

Referring to FIG. 1J, the second patterned photoresist layer PR2, the third patterned photoresist layer PR3, the metal pattern 121b, and the second metal material layer 122a are removed after the element region R1, the support region R2, and the dividing region R3 are formed. The manufacture of the piezoelectric vibration element 100 is roughly completed through the above manufacturing. The piezoelectric vibration element 100 manufactured through the aforementioned manufacturing method may be in the shape of a flat sheet. In other words, the piezoelectric vibration element 100 is not in the shape of a tuning fork. In addition, the support structure 160 on the support region R2 and the piezoelectric vibration element 100 on the element region R1 may form an H-type structure (for example, thickness of the two sides is greater than the thickness of the middle and the width of the two sides is smaller than the width of the middle). In this way, the support structure 160 is configured to improve the structural strength in the process and reduce the risk of wafer breakage, but the disclosure is not limited thereto.

In some embodiments, as shown in FIG. 2, the support region R2 may surround a plurality of element regions R1 divided by the dividing region R3, but the disclosure is not limited thereto.

It should be noted that although the first surface 111 in the drawing is an upper surface of the quartz wafer 110, the disclosure is not limited thereto. In the embodiment that is not shown, the first surface may also be a lower surface of the quartz wafer. As long as the exposure and development process is only performed on one side to form the metal pattern for forming the plane size of the piezoelectric vibration element, it all falls within the protection scope of the disclosure.

To sum up, the manufacturing method of the piezoelectric vibration element of the disclosure is designed to simplify the process. That is, the manufacturing method of the piezoelectric vibration element of the disclosure only performs one exposure and development process on the photoresist material layer on one side of the quartz wafer, and does not perform a secondary exposure and development process on the photoresist material layer on two sides of the quartz wafer at the same time. The metal pattern defined by the photoresist layer after the exposure and development process may still be used to define the plane size of the piezoelectric vibration element on the other side, which reduces the manufacturing cost while maintaining the precise requirements of the piezoelectric vibration element.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A manufacturing method of a piezoelectric vibration element, comprising:
providing a quartz wafer, wherein the quartz wafer has a first surface and a second surface opposite to each other;
fully forming a first metal material layer and a second metal material layer on the first surface and the second surface, respectively;
fully forming a first photoresist material layer and a second photoresist material layer on the first metal material layer and the second metal material layer, respectively;
performing an exposure and development process only on the first photoresist material layer to form a first patterned photoresist layer;
removing a portion of the first metal material layer by the first patterned photoresist layer to form a metal pattern; and
removing the first patterned photoresist layer and the second photoresist material layer.

2. The manufacturing method of the piezoelectric vibration element according to claim 1, further comprising:
fully forming a third photoresist material layer and a fourth photoresist material layer on the metal pattern and the second metal material layer; and
performing an exposure and development processes respectively on the third photoresist material layer and the fourth photoresist material layer to form a second patterned photoresist layer and a third patterned photoresist layer.

3. The manufacturing method of the piezoelectric vibration element according to claim 2, further comprising:
removing a first portion of the quartz wafer by the metal pattern and the second patterned photoresist layer to form a groove pattern extending from the first surface into the quartz wafer.

4. The manufacturing method of the piezoelectric vibration element according to claim 3, wherein after the groove pattern is formed, the method further comprising:
removing a portion of the metal pattern by the second patterned photoresist layer;
removing a portion of the second metal material layer by the third patterned photoresist layer; and
removing a second portion of the quartz wafer, such that the plurality of groove patterns are extended and penetrated through the second surface.

5. The manufacturing method of the piezoelectric vibration element according to claim 4, wherein an element region, a support region, and a dividing region are formed after the second portion of the quartz wafer is removed, and the dividing region is located between the element region and the support region.

6. The manufacturing method of the piezoelectric vibration element according to claim 5, wherein the second patterned photoresist layer, the third patterned photoresist layer, another portion of the metal pattern, and another portion of the second metal material layer are removed after the element region, the support region, and the dividing region are formed.

7. The manufacturing method of the piezoelectric vibration element according to claim 5, wherein a support structure on the support region and the piezoelectric vibration element on the element region form an H-structure after the second portion of the quartz wafer is removed.

8. The manufacturing method of the piezoelectric vibration element according to claim 1, wherein the piezoelectric vibration element is a flat sheet.

9. The manufacturing method of the piezoelectric vibration element according to claim 1, wherein a thickness of the piezoelectric vibration element is at least less than 50 micrometers.
